(19) United States
(12) Patent Application Publication
(10) Pub. No.: US 2024/0049611 A1
(43) Pub. Date: Feb. 8, 2024

(54) RESISTIVE MEMORY DEVICES WITH A CAVITY BETWEEN ELECTRODES

(71) Applicant: GlobalFoundries Singapore Pte. Ltd., Singapore (SG)

(72) Inventors: CURTIS CHUN-I HSIEH, Singapore (SG); JUAN BOON TAN, Singapore (SG); WEI-HUI HSU, Singapore (SG); WANBING YI, Singapore (SG); KAI KANG, Singapore (SG)

(21) Appl. No.: 17/817,430

(22) Filed: Aug. 4, 2022

(51) Int. Cl. H01L 45/00; H01L 27/24

(52) U.S. Cl. CPC H01L 45/1233; H01L 45/1253; H01L 27/2481

(57) ABSTRACT

The disclosed subject matter relates generally to resistive memory devices and methods of forming the same. More particularly, the present disclosure relates to two terminal and three terminal resistive random-access (ReRAM) memory devices with a cavity arranged between electrodes.

### FIELD OF THE INVENTION

The disclosed subject matter relates generally to resistive memory devices and methods of forming the same. More particularly, the present disclosure relates to two terminal and three terminal resistive random-access (ReRAM) memory devices with a cavity arranged between electrodes.

### BACKGROUND

Semiconductor devices and integrated circuit (IC) chips have found numerous applications in the fields of physics, chemistry, biology, computing, and memory devices. An example of a memory device is a non-volatile (NV) memory device. NV memory devices are programmable and have been extensively used in electronic products due to their ability to retain data for long periods, even after the power has been turned off. Exemplary categories for NV memory may include resistive random-access memory (ReRAM), erasable programmable read-only memory (EPROM), flash memory, ferroelectric random-access memory (FeRAM), and magnetoresistive random-access memory (MRAM).

Resistive memory devices can operate by changing (or switching) between two different states: a high resistance state (HRS), which may be representative of an off or ‘0’ state; and a low resistance state (LRS), which may be representative of an on or ‘1’ state. However, these devices may experience large variations in resistive switching characteristics and may cause large fluctuations of current flow within the device, which decreases the performance of the device and increases its power consumption.

Resistive memory devices may also be connected to other circuit components in an IC chip using various interconnection schemes, such as metal lines or interconnect structures. With further miniaturization of the IC chips, the parasitic capacitance and resistance of the interconnection schemes may increase at smaller scales or process nodes and may degrade the chip performance significantly. The presence of parasitic capacitances may cause unwanted current spikes or overshoot due to the charging or discharging of additional current during the switching of the resistance states in the resistive memory device. The current overshoot may cause a breakdown of the dielectric insulation around the interconnect structures and an electrical short.

Therefore, there is a need to provide improved resistive memory devices that can overcome, or at least ameliorate, one or more of the problems described above.

### SUMMARY

In an aspect of the present disclosure, there is provided a resistive memory device including a first dielectric pillar having an upper surface, a second dielectric pillar adjacent to the first dielectric pillar, the second dielectric pillar having an upper surface, a first bottom electrode having a top segment on the upper surface of the first dielectric pillar, a second bottom electrode having a top segment disposed on the upper surface of the second dielectric pillar, a switching layer laterally between the first bottom electrode and the second bottom electrode, and a cavity defined laterally between the first dielectric pillar and the second dielectric pillar. The top segment of the first bottom electrode includes an upper surface and a side surface, the side surface of the top segment meets the upper surface of the top segment to provide a first bottom electrode top edge. The top segment of the second bottom electrode includes an upper surface and a side surface, the side surface of the top segment meets the upper surface of the top segment to provide a second bottom electrode top edge. The switching layer is in direct contact with the first bottom electrode top edge and the second bottom electrode top edge. The cavity is bounded by at least the first bottom electrode, the second bottom electrode, and the switching layer, in which the switching layer is positioned over the cavity.

In another aspect of the present disclosure, there is provided a resistive memory device including a first dielectric pillar having an upper surface, a second dielectric pillar adjacent to the first dielectric pillar, the second dielectric pillar having an upper surface, a first dielectric cap on the upper surface of the first dielectric pillar, a second dielectric cap on the upper surface of the second dielectric pillar, a first bottom electrode having a top segment covering the first dielectric cap, a second bottom electrode having a top segment covering the second dielectric cap, a switching layer laterally between the first bottom electrode and the second bottom electrode, and a cavity defined laterally between the first dielectric pillar and the second dielectric pillar. The top segment of the first bottom electrode includes an upper surface and a side surface, the side surface of the top segment meets the upper surface of the top segment to provide a first bottom electrode top edge. The top segment of the second bottom electrode includes an upper surface and a side surface, the side surface of the top segment meets the upper surface of the top segment to provide a second bottom electrode top edge. The switching layer is in direct contact with the first bottom electrode top edge and the second bottom electrode top edge. The cavity is bounded by at least the first bottom electrode, the second bottom electrode, and the switching layer, in which the switching layer is positioned over the cavity.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1A, FIG. 1B, and FIG. 1C are cross-sectional views of exemplary two terminal resistive memory devices.

FIG. 2A, FIG. 2B, and FIG. 2C are cross-sectional views of exemplary three terminal resistive memory devices.

FIG. 3A is an enlarged cross-sectional view of section 200, outlined by a broken-lined rectangle, in FIG. 1A.

FIG. 3B is an enlarged cross-sectional view of section 200, outlined by a broken-lined rectangle, in FIG. 2A.

FIG. 3C is an enlarged cross-sectional view of section 200, outlined by a broken-lined rectangle, in FIG. 1B.

FIG. 3D is an enlarged cross-sectional view of section 200, outlined by a broken-lined rectangle, in FIG. 2B.

FIG. 4 is an enlarged cross-sectional view of section 300, outlined by a broken-lined rectangle in FIG. 3B and FIG. 3D.

FIG. 5A to FIG. 5D are cross-sectional views of example modifications of the resistive memory devices shown in FIG. 1A to FIG. 1C.

FIG. 6A to FIG. 6D are cross-sectional views of example modifications of the resistive memory devices shown in FIG. 2A to FIG. 2C.

FIG. 7A, FIG. 7B, FIG. 8A to FIG. 8D, and FIG. 9 to FIG. 19 are cross-sectional views depicting structures at various stages of fabricating the exemplary resistive memory devices described herein.

FIG. 7A, FIG. 7B, and FIG. 8A to FIG. 8D are cross-sectional views depicting example structures at a stage of forming dielectric pillars.

FIG. 9 to FIG. 12 are cross-sectional views depicting example structures at a stage of forming bottom electrodes over the dielectric pillars.

FIG. 13 to FIG. 16 are cross-sectional views depicting example structures at a stage of forming switching layers between the bottom electrodes.

FIG. 17 to FIG. 19 are cross-sectional views depicting example structures at a stage of forming top electrodes over the switching layer.

### DETAILED DESCRIPTION

Various illustrative embodiments of the present disclosure are described below. The embodiments disclosed herein are exemplary and not intended to be exhaustive or limiting to the present disclosure.

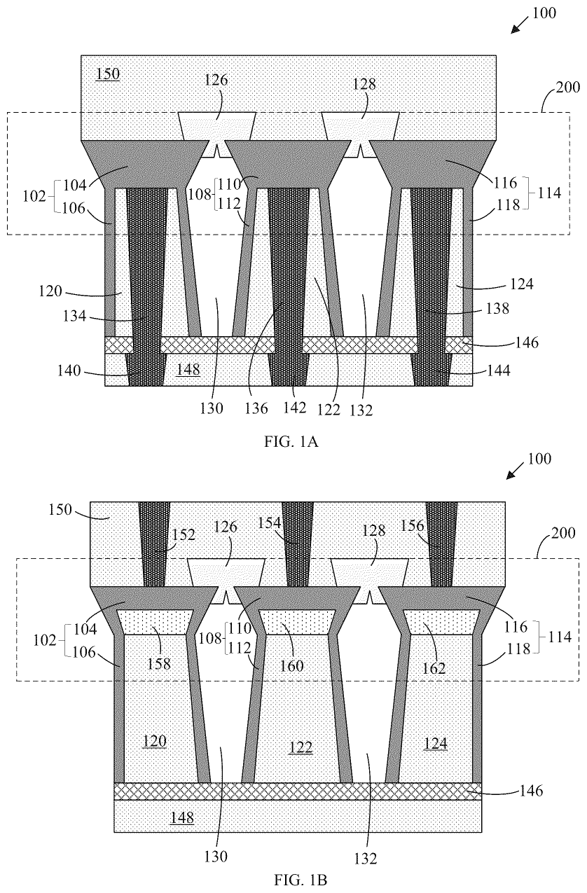

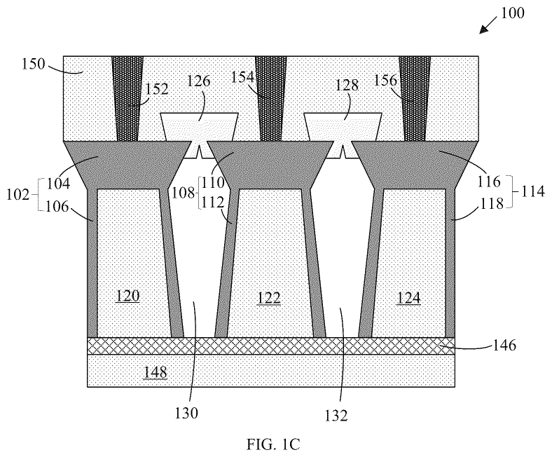

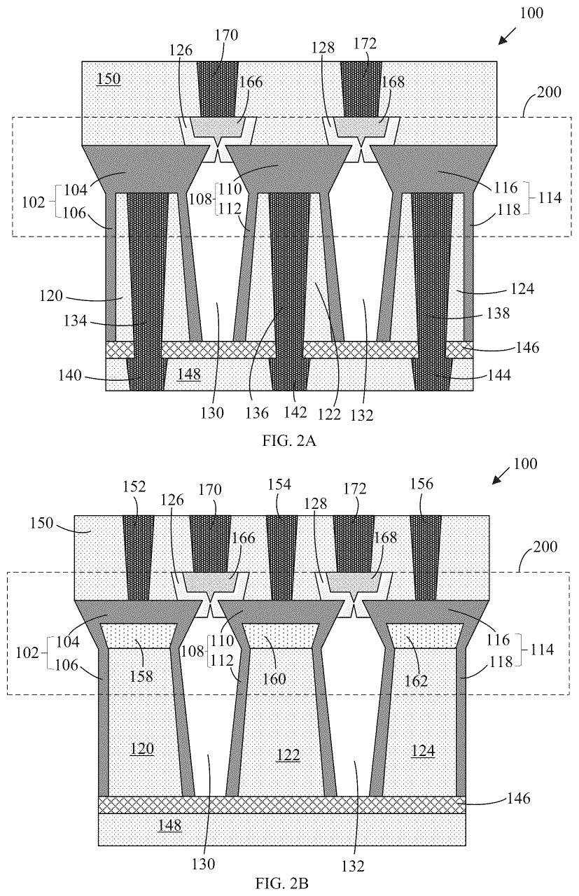

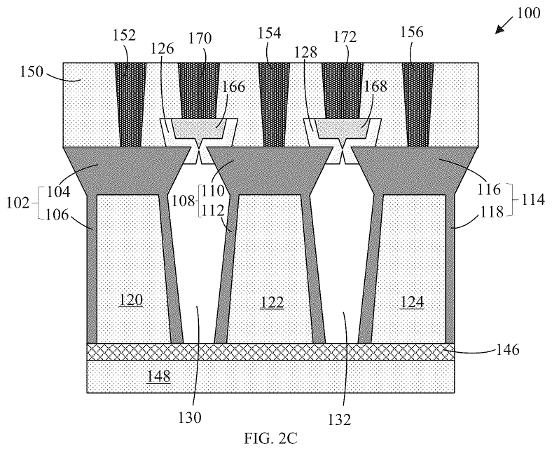

Referring to FIG. 1A to FIG. 1C, and FIG. 2A to FIG. 2C, examples of a memory device 100 may include a plurality of dielectric pillars, such as a first dielectric pillar 120, a second dielectric pillar 122, and a third dielectric pillar 124. The dielectric pillars 120, 122, 124 may be adjacent to and spaced apart from each other. Bottom electrodes 102, 108, 114 may be positioned over the dielectric pillars 120, 122, 124. For example, a first bottom electrode 102 may be positioned over the first dielectric pillar 120, a second bottom electrode 108 may be positioned over the second dielectric pillar 122, and a third bottom electrode 114 may be positioned over the third dielectric pillar 124. Each of the bottom electrodes 102, 108, 114 may have a top segment and a bottom segment. For example, the first bottom electrode 102 may have a top segment 104 on an upper surface of the first dielectric pillar 120 and a bottom segment 106 on a side surface of the first dielectric pillar 120. The second bottom electrode 108 may have a top segment 110 on an upper surface of the second dielectric pillar 122 and a bottom segment 112 on a side surface of the second dielectric pillar 122. The third bottom electrode 114 may have a top segment 116 on an upper surface of the third dielectric pillar 124 and a bottom segment 118 on a side surface of the third dielectric pillar 124. The dielectric pillars 120, 122, 124 may include, but are not limited to, silicon dioxide, tetraethyl orthosilicate (TEOS), or a material having a chemical composition of SiCₓO_{y}H_{z}, wherein x, y, and z are in stoichiometric ratio.

Switching layers 126, 128 may be positioned laterally between the bottom electrodes 102, 108, 114. For example, a first switching layer 126 may be positioned laterally between the first bottom electrode 102 and the second bottom electrode 108. A second switching layer 128 may be positioned laterally between the second bottom electrode 108 and the third bottom electrode 114. Examples of the material for the switching layers 126, 128 may include, but are not limited to, carbon polymers, perovskites, silicon dioxide, metal oxides, or nitrides. Some examples of metal oxides may include lanthanide oxides, tungsten oxide, copper oxide, cobalt oxide, silver oxide, zinc oxide, nickel oxide, niobium oxide, titanium oxide, hafnium oxide, aluminum oxide, tantalum oxide, zirconium oxide, yttrium oxide, scandium oxide, magnesium oxide, chromium oxide, and vanadium oxide. Examples of nitrides may include boron nitride and aluminum nitride.

Cavities 130, 132 may be defined laterally between the dielectric pillars 120, 122, 124. For example, a first cavity 130 may be laterally between the first dielectric pillar 120 and the second dielectric pillar 122. The first cavity 130 may be bounded by at least the first bottom electrode 102, the second bottom electrode 108, and the first switching layer 126. The first switching layer 126 may be positioned over the first cavity 130. A second cavity 132 may be laterally between the second dielectric pillar 122 and the third dielectric pillar 124. The second cavity 132 may be bounded by at least the second bottom electrode 108, the third bottom electrode 114, and the second switching layer 128. The second switching layer 128 may be positioned over the second cavity 132. The cavities 130, 132 may be filled with gas, such as air, nitrogen, or inert gas.

In some examples, an etch stop layer 146 may be positioned below the dielectric pillars 120, 122, 124. The etch stop layer 146 may include, but is not limited to, silicon dioxide (SiO₂), silicon oxynitride (SiON), silicon nitride (SiN), Nitrogen doped silicon carbide (SiCN), SiCₓH_{z} (i.e., BLoK™), or SiN_{w}CₓH_{z} (i.e., NBLoK™), wherein each of w, x, y, and z independently has a value greater than 0 and less than 0.75. The etch stop layer 146 may be positioned on a dielectric layer 148. In the examples shown in FIG. 1A to FIG. 1C, and FIG. 2A to FIG. 2C, the first cavity 130 may be bounded by at least the top 104 and bottom 106 segments of the first bottom electrode 102, the top 110 and bottom 112 segments of the second bottom electrode 108, the first switching layer 126, and the etch stop layer 146, while the second cavity 132 may be bounded by at least the top 110 and bottom 112 segments of the second bottom electrode 108, the top 116 and bottom 118 segments of the third bottom electrode 114, the second switching layer 128, and the etch stop layer 146. The dielectric pillars 120, 122, 124 may be positioned on or directly on the etch stop layer 146. The dielectric pillars 120, 122, 124 may include a material that is different from the material of the etch stop layer 146.

A dielectric layer 150 may be positioned over the bottom electrodes 102, 108, 114 and the switching layers 126, 128. The dielectric layers 148, 150 may be formed by the back end of line (BEOL) processing of an IC chip. The memory device 100 may include a plurality of dielectric layers. The number of dielectric layers may depend on, for example, design requirements or the process involved. The dielectric layers 148, 150 may include, but are not limited to, silicon dioxide, tetraethyl orthosilicate (TEOS), or a material having a chemical composition of SiCₓO_{y}H_{z}, wherein x, y, and z are in stoichiometric ratio. The resistive memory device 100 may be integrated into an IC chip (not shown). The bottom electrodes 102, 108, 114 may be connected to other circuit components in the IC chip using interconnect features. The interconnect features may be formed in the dielectric layers 148, 150 and the dielectric pillars 120, 122, 124. Examples of the interconnect features may include interconnect vias or conductive lines.

In the examples shown in FIG. 1A and FIG. 2A, the bottom electrodes 102, 108, 114 may be connected to interconnect vias 134, 136, 138, respectively. Preferably, the top segments 104, 110, 116 of the bottom electrodes 102, 108, 114 may be positioned upon the interconnect vias 134, 136, 138. The interconnect vias 134, 136, 138 may be positioned below the bottom electrodes 102, 108, 114 and may be formed in the respective dielectric pillars 120, 122, 124. Conductive lines 140, 142, 144 may be formed in the dielectric layer 148 and may provide routing or wiring of electrical signals to the other circuit components in the IC chip. The interconnect vias 134, 136, 138 may be formed on the conductive lines 140, 142, 144, respectively. The inclusion of the cavities 130, 132 laterally between the dielectric pillars 120, 122, 124 may decrease the occurrence of parasitic capacitances between the interconnect features formed in the dielectric pillars 120, 122, 124 and the dielectric layer 148, thereby reducing the charging effect improving chip performance. Alternatively, in examples shown in FIG. 1B, FIG. 1C, FIG. 2B, and FIG. 2C, interconnect vias 152, 154, 156 may be formed in the dielectric layer 150 and may be connected to the bottom electrodes 102, 108, 114, respectively. The interconnect vias 152, 154, 156 may be positioned above bottom electrodes 102, 108, 114. Preferably, the interconnect vias 152, 154, 156 may be positioned directly on the top segments 104, 110, 116 of the bottom electrodes 102, 108, 114.

In some examples, as shown in FIG. 1B and FIG. 2B, the resistive memory device 100 may further include dielectric caps 158, 160, 162 positioned on the respective upper surfaces of the dielectric pillars 120, 122, 124. For example, a first dielectric cap 158 may be positioned on or directly on the upper surface of the first dielectric pillar 120, a second dielectric cap 160 may be positioned on or directly on the upper surface of the second dielectric pillar 122, a third dielectric cap 162 may be positioned on or directly on the upper surface of the third dielectric pillar 124. The top segment 104 of the first bottom electrode 102 may cover the first dielectric cap 158. The top segment 110 of the second bottom electrode 108 may cover the second dielectric cap 160. The top segment 116 of the third bottom electrode 114 may cover the third dielectric cap 162. Alternatively, in the examples shown in FIG. 1A, FIG. 1C, FIG. 2A, and FIG. 2C, the dielectric caps 158, 160, 162 may be absent and the respective top segments 104, 110, 116 of the bottom electrodes 102, 108, 114 may be positioned directly on the upper surfaces of the dielectric pillars 120, 122, 124, respectively. The dielectric caps 158, 160, 162 may include a material that is different from the material in the dielectric pillars 120, 122, 124. The dielectric caps 158, 160, 162 may include, for example, oxides of silicon.

Referring to FIG. 2A, FIG. 2B, and FIG. 2C, the resistive memory device 100 may further include top electrodes 166, 168 positioned on the switching layers 126, 128. For example, a first top electrode 166 may be positioned on or directly on the first switching layer 126 and a second top electrode 168 may be positioned on or directly on the second switching layer 128. The dielectric layer 150 may be formed over the top electrodes 166, 168. Interconnect vias 170, 172 may be formed in the dielectric layer 150 and may be connected to the respective top electrodes 166, 168. For example, the interconnect vias 170, 172 may be formed directly on the top electrodes 166, 168.

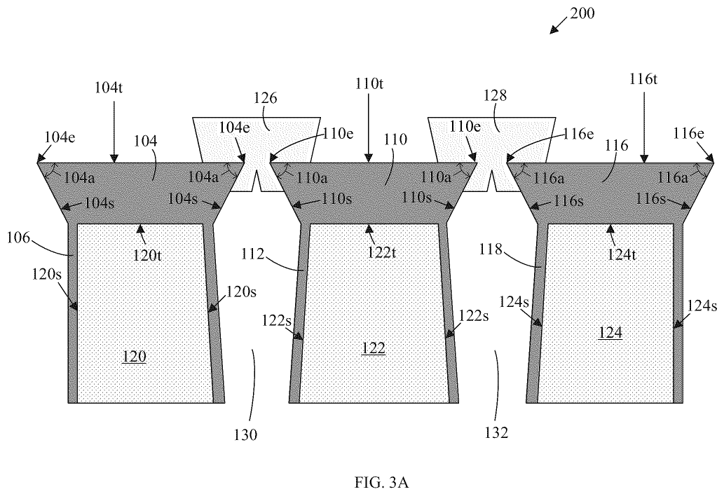

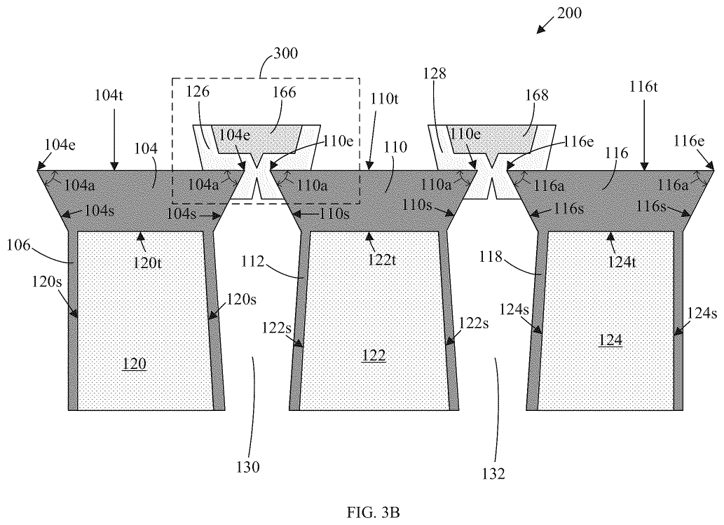

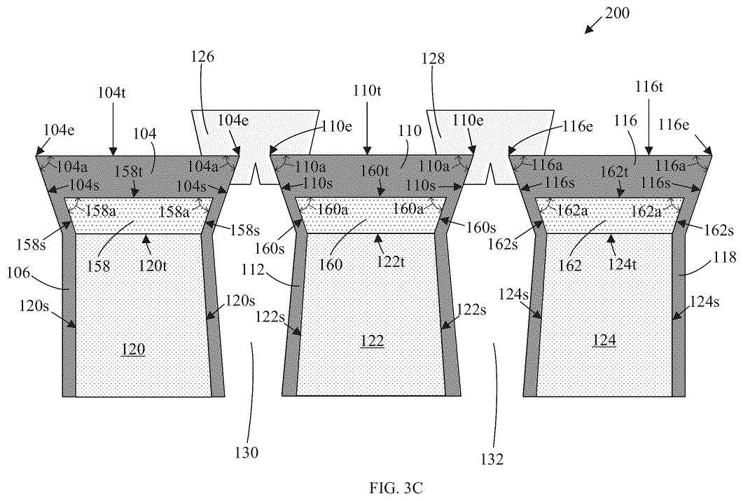

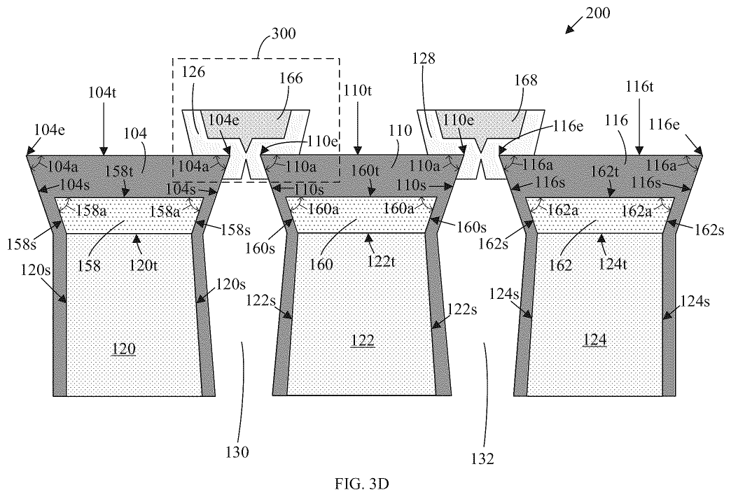

FIG. 3A to FIG. 3D are enlarged cross-sectional views depicting the dielectric pillars 120, 122, 124, the respective top segments 104, 110, 116 and bottom segments 106, 112, 118 of the bottom electrodes, the dielectric caps 158, 160, 162, and the switching layers 126, 128. FIG. 3B and FIG. 3D additionally depict the top electrodes 166, 168. For simplicity, the interconnect vias and the dielectric layers are not shown in FIG. 3A to FIG. 3D. Referring to FIG. 3A to FIG. 3D, the first dielectric pillar 120 may have an upper surface 120t and a side surface 120s, the second dielectric pillar 122 may have an upper surface 122t and a side surface 122s, and the third dielectric pillar 124 may have an upper surface 124t and a side surface 124s.

In the examples shown in FIG. 3A and FIG. 3B, the top segment 104 of the first bottom electrode may be positioned on or directly on the upper surface 120t of the first dielectric pillar 120 and the bottom segment 106 of the first bottom electrode may be positioned on or directly on the side surface 120s of the first dielectric pillar 120. The top segment 110 of the second bottom electrode may be positioned on or directly on the upper surface 122t of the second dielectric pillar 122 and the bottom segment 112 of the second bottom electrode may be positioned on or directly on the side surface 122s of the second dielectric pillar 122. The top segment 116 of the third bottom electrode may be positioned on or directly on the upper surface 124t of the third dielectric pillar 124 and the bottom segment 118 of the third bottom electrode may be positioned on or directly on the side surface 124s of the third dielectric pillar 124.

In the examples shown in FIG. 3C and FIG. 3D, the first dielectric cap 158 may be positioned on or directly on the upper surface 120t of the first dielectric pillar 120. The second dielectric cap 160 may be positioned on or directly on the upper surface 122t of the second dielectric pillar 122. The third dielectric cap 162 may be positioned on or directly on the upper surface 124t of the third dielectric pillar 124. The first dielectric cap 158 may have an upper surface 158t and a side surface 158s, in which the side surface 158s of the first dielectric cap 158 may form an acute angle 158a with the upper surface 158t of the first dielectric cap 158. The second dielectric cap 160 may have an upper surface 160t and a side surface 160s, in which the side surface 160s of the second dielectric cap 160 may form an acute angle 160a with the upper surface 160t of the second dielectric cap 160. The third dielectric cap 162 may have an upper surface 162t and a side surface 162s, in which the side surface 162s of the third dielectric cap 162 may form an acute angle 162a with the upper surface 162t of the third dielectric cap 162. The acute angles 158a, 160a, 162a may be between 1 degree to 89 degrees, and preferably, between 30 degrees to 60 degrees.

The top segment 104 of the first bottom electrode may be positioned on or directly on the upper surface 158t of the first dielectric cap 158 and the bottom segment 106 of the first bottom electrode may be positioned on or directly on the side surface 158s of the first dielectric cap 158. The bottom segment 106 of the first bottom electrode may extend to lie on or directly on the side surfaces 120s of the first dielectric pillar 120. The top segment 110 of the second bottom electrode may be positioned on or directly on the upper surface 160t of the second dielectric cap 160 and the bottom segment 112 of the second bottom electrode may be positioned on or directly on the side surface 160s of the second dielectric cap 160. The bottom segment 112 of the second bottom electrode may extend to lie on or directly on the side surfaces 122s of the second dielectric pillar 122. The top segment 116 of the third bottom electrode may be positioned on or directly on the upper surface 162t of the third dielectric cap 162 and the bottom segment 118 of the third bottom electrode may be positioned on or directly on the side surface 162s of the third dielectric cap 162. The bottom segment 118 of the third bottom electrode may extend to lie on or directly on the side surfaces 124s of the third dielectric pillar 124.

Referring again to FIG. 3A to FIG. 3D, the top segment 104 of the first bottom electrode may include an upper surface 104t and a side surface 104s. The side surface 104s of the top segment 104 of the first bottom electrode may meet the upper surface 104t of the top segment 104 of the first bottom electrode to provide a first electrode top edge 104e. The side surface 104s of the top segment 104 of the first bottom electrode may form an acute angle 104a with the upper surface 104t of the top segment 104 of the first bottom electrode. The top segment 110 of the second bottom electrode may include an upper surface 110t and a side surface 110s. The side surface 110s of the top segment 110 of the second bottom electrode may meet the upper surface 110t of the top segment 110 of the second electrode to provide a second bottom electrode top edge 110e. The side surface 110s of the top segment 110 of the second bottom electrode may form an acute angle 110a with the upper surface 110t of the top segment 110 of the second bottom electrode. The top segment 116 of the third bottom electrode may include an upper surface 116t and a side surface 116s. The side surface 116s of the top segment 116 of the third bottom electrode may meet the upper surface 116t of the top segment 116 of the third bottom electrode to provide a third bottom electrode top edge 116e. The side surface 116s of the top segment 116 of the third bottom electrode may form an acute angle 116a with the upper surface 116t of the top segment 116 of the third bottom electrode. The acute angles 104a, 110a, 116a may have a value between 1 degree to 89 degrees, and preferably, between 30 degrees to 60 degrees.

In the examples shown in FIG. 3A and FIG. 3B, the respective upper surfaces 104t, 110t, 116t of the top segments 104, 110, 116 of the bottom electrodes may have a larger surface area than the respective upper surfaces 120t, 122t, 124t of the dielectric pillars 120, 122, 124. In the example shown in FIG. 3C, the respective upper surfaces 104t, 110t, 116t of the top segments 104, 110, 116 of the bottom electrodes may have a larger surface area than the respective upper surfaces 158t, 160t, 162t of the dielectric caps 158, 160, 162.

The first bottom electrode top edge 104e and the second bottom electrode top edge 110e may form overhangs extending over the first cavity 130. The second bottom electrode top edge 110e and the third bottom electrode top edge 116e may form overhangs extending over the second cavity 132. As described above, the first switching layer 126 may be positioned over the first cavity 130 while the second switching layer 128 may be positioned over the second cavity 132. The first switching layer 126 may be in direct contact with the first bottom electrode top edge 104e and the second bottom electrode top edge 110e. The second switching layer 128 may be in direct contact with the second bottom electrode top edge 110e and the third bottom electrode top edge 116e. The switching layers 126, 128 may be configured to have a switchable resistance in response to a change in an electric signal. For example, the first switching layer 126 may include a conductive path configured to form between the first bottom electrode top edge 104e and the second bottom electrode top edge 110e in response to a change in the electric signal. The second switching layer 128 may include a conductive path configured to form between the second bottom electrode top edge 110e and the third bottom electrode top edge 116e in response to a change in the electric signal. The presence of the conductive paths may reduce the resistance of the respective switching layers 126, 128 while the absence of the conductive paths may increase the resistance of the switching layers 126, 128, thereby enabling a controllable resistive nature of the switching layers 126, 128. The switching layers 126, 128 may exhibit resistive changing properties characterized by different resistance states of the material forming this layer. These resistance states (e.g., a high resistance state (HRS) or a low resistance state (LRS)) may be used to represent one or more bits of information.

The formation of acute angles 104a, 110a, 116a between the respective upper surfaces 104t, 110t, 116t and the respective side surfaces 104s, 110s, 116s may provide sharp bottom electrode top edges 104e, 110e, 116e where strong localization of electric fields (i.e., the largest concentration of electric charges) can be found. With the strong localization of electric fields at the respective bottom electrode top edges 104e, 110e, 116e, the conductive paths formed between the first bottom electrode top edge 104e and the second bottom electrode top edge 110e as well as between the second bottom electrode top edge 110e and the third bottom electrode top edge 116e can be confined and do not form randomly along the length of the switching layers 126, 128. The confinement of the conducting paths may help to reduce the stochasticity of their formation, which in turn reduces the cycle-to-cycle and device-to-device variability of the resistive memory devices in the high resistive state. In other words, the variability of the resistance of the switching layers 126, 128 in the high resistive state may be reduced. This may enable a stable switching of the resistive states in the switching layers 126, 128 during the operation of the device and may reduce its overall power consumption.

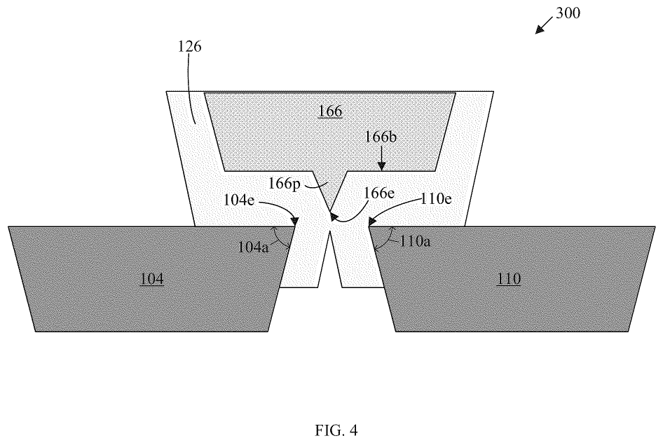

Referring to FIG. 4, an enlarged cross-sectional view of the top electrode 166, the switching layer 126, the top segment 104 of the first electrode and the top segment of the 110 of the second electrode are presented. For simplicity, the interconnect vias and the dielectric layers are not shown in FIG. 4. The top electrode 166 may include a bottom surface 166b and a protrusion 166p extending from the bottom surface 166b into the switching layer 126. Conductive paths may be formed between the protrusion 166p of the top electrode 166 and the first bottom electrode top edge 104e, as well as between the protrusion 166p of the top electrode 166 and the second bottom electrode top edge 110e. The protrusion 166p may have a pointed edge 166e such that a larger concentration of electric charges may accumulate at the protrusion 166p of the top electrode 166, thereby providing a strong localization of electric field. With the strong localization of electric fields at the bottom electrode top edges 104e, 110e and the protrusion 166p of the top electrode 166, the conductive paths formed between the protrusion 166p of the top electrode 166 and the first bottom electrode top edge 104e, as well as between the protrusion 166p of the top electrode 166 and the second bottom electrode top edge 110e can be confined and do not form randomly along the length of the switching layer 126.

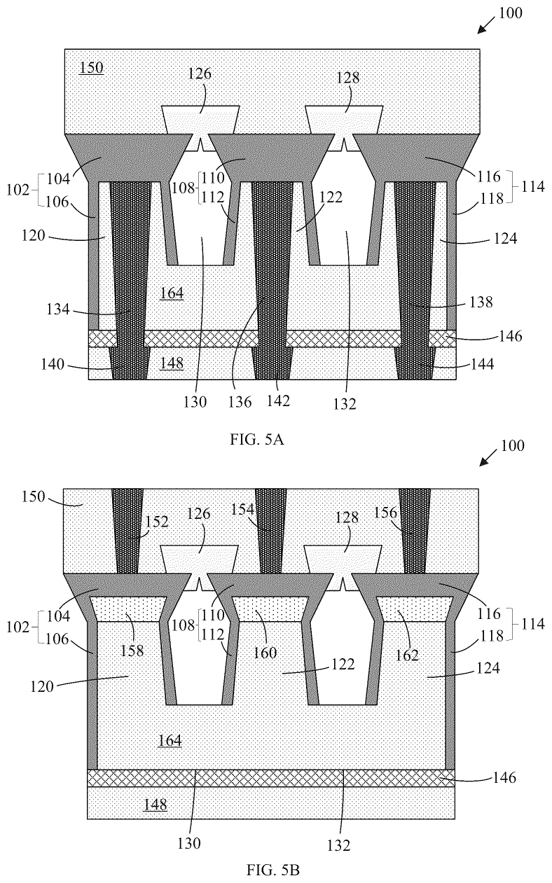

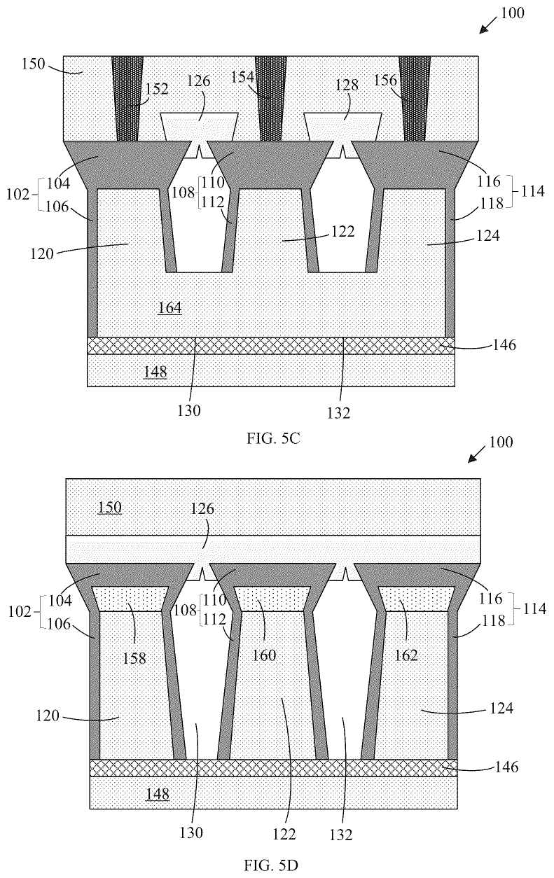

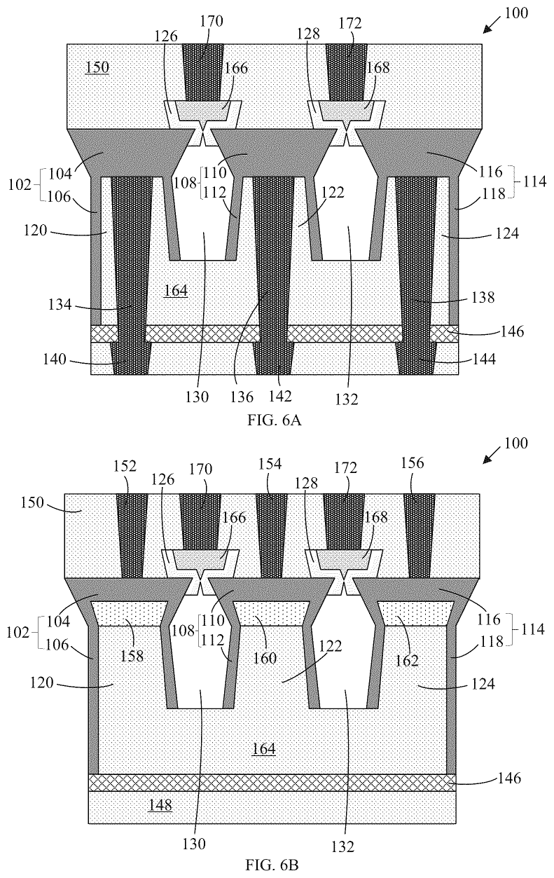

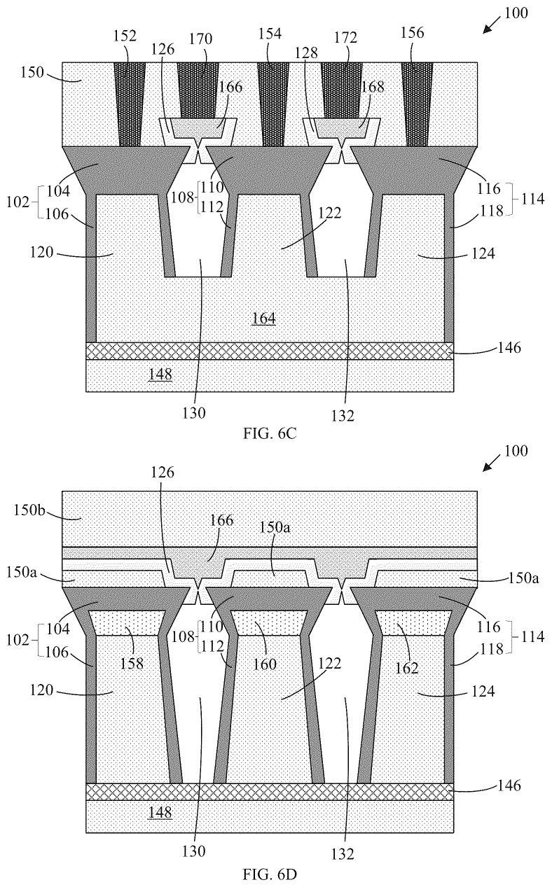

Referring to FIG. 5A to FIG. 5C and FIG. 6A to FIG. 6C, in which like reference numerals in FIG. 5A to FIG. 5C refer to like features in FIG. 1A to FIG. 1C and like reference numerals in FIG. 6A to FIG. 6C refer to like features in FIG. 2A to FIG. 2C, example modifications of the resistive memory device 100 are presented. The resistive memory device 100 may further include a dielectric layer 164 below the dielectric pillars 120, 122, 124. The dielectric pillars 120, 122, 124 may be integrally formed with the dielectric layer 164. The etch stop layer 146 may be positioned below the dielectric layer 164 such that the dielectric pillars 120, 122, 124 may be on or directly on the dielectric layer 164. In the examples shown in FIG. and FIG. 6A, the interconnect vias 134, 136, 138 may be formed in the respective dielectric pillars 120, 122, 124 and extend through the underlying dielectric layer 164 and the etch stop layer 146.

In the examples shown in FIG. 5A to FIG. 5C and FIG. 6A to FIG. 6C, the first cavity 130 may be bounded by at least the top 104 and bottom 106 segments of the first bottom electrode 102, the top 110 and bottom 112 segments of the second bottom electrode 108, the first switching layer 126, and the dielectric layer 164, while the second cavity 132 may be bounded by at least the top 110 and bottom 112 segments of the second bottom electrode 108, the top 116 and bottom 118 segments of the third bottom electrode 114, the second switching layer 128, and the dielectric layer 164. The dielectric layer 164 may include, but is not limited to, silicon dioxide, tetraethyl orthosilicate (TEOS), or a material having a chemical composition of SiCₓO_{y}H_{z}, wherein x, y, and z are in stoichiometric ratio.

Referring to FIG. 5D and FIG. 6D, in which like reference numerals refer to like features in FIG. 1B and FIG. 2B, respectively, another example modifications of the resistive memory device 100 are presented. In the example shown in FIG. 5D, the switching layer 126 may be positioned between the bottom electrodes 102, 108, 114 and extend laterally over the dielectric pillars 120, 122, 124. In the example shown in FIG. 6D, the switching layer 126 and the top electrode 166 may be positioned between the bottom electrodes 102, 108, 114 and extend laterally over the dielectric pillars 120, 122, 124. A dielectric layer 150a may be positioned on or directly on the respective top segments 104, 110, 116 of the bottom electrodes 102, 108, 114. The switching layer 126 may be positioned on or directly on the dielectric layer 150a. The top electrode 166 may be positioned on or directly on the switching layer 126. A dielectric layer 150b may be positioned on or directly on the top electrode 166. The lateral extension of the switching layer 126 over the dielectric pillars 120, 122, 124 as shown in FIG. 5D and the lateral extension of the switching layer 126 and the top electrode 166 over the dielectric pillars 120, 122, 124 shown in FIG. 6D may be contemplated as being applicable to the examples shown in FIG. 1A to FIG. 1C, FIG. 2A to FIG. 2C, FIG. 5A to FIG. 5C, and FIG. 6A to FIG. 6C.

The bottom electrodes 102, 108, 114 and the top electrodes 166, 168 described herein may include a conductive material. Examples of the conductive material may include, but are not limited to, tantalum (Ta), hafnium (Hf), titanium (Ti), copper (Cu), silver (Ag), cobalt (Co), tungsten (W), an oxide thereof, or an alloy thereof, ruthenium (Ru), platinum (Pt), titanium nitride (TiN), tantalum nitride (TaN). The interconnect vias 134, 136, 138, 152, 154, 156, 170, 172 and the conductive lines 140, 142, 144 described herein may include a metal, such as cobalt (Co), copper (Cu), aluminum (Al), or an alloy thereof. Other suitable types of metals or alloys may also be useful.

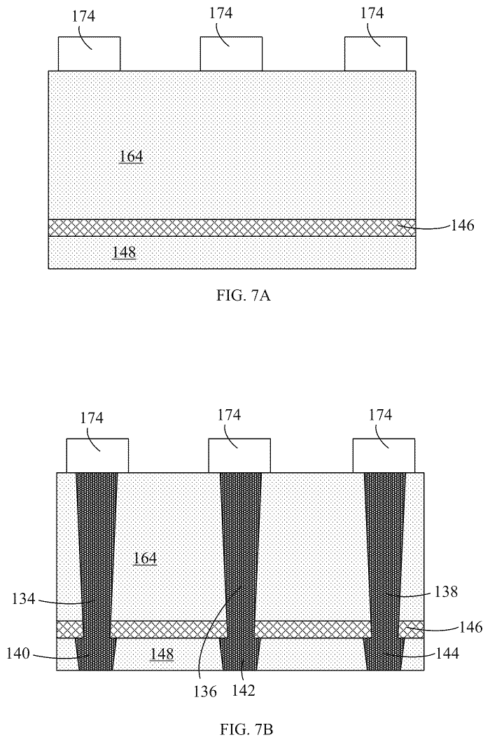

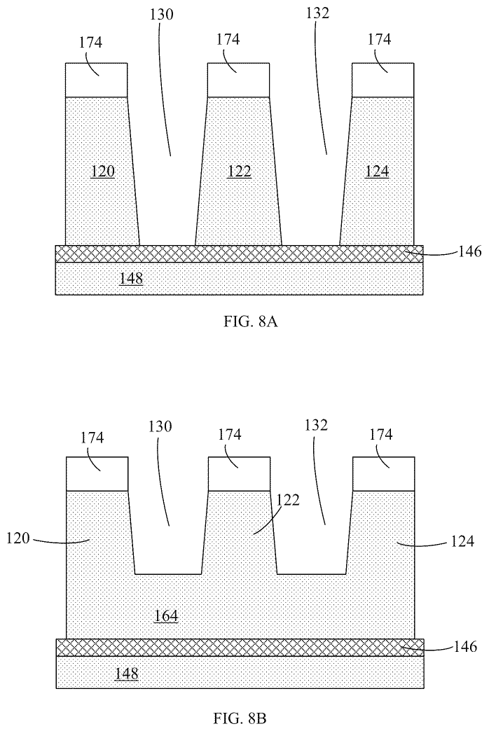

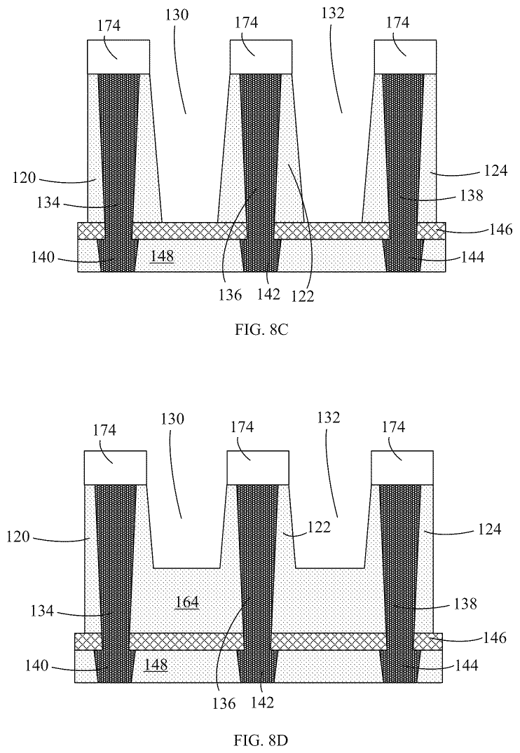

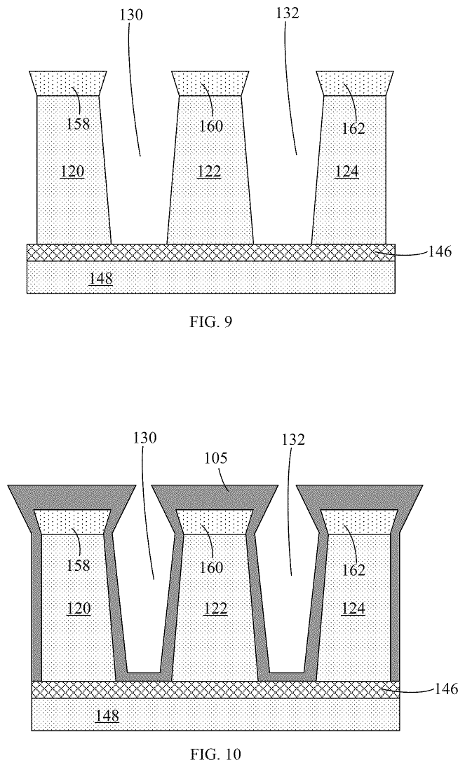

FIG. 7A, FIG. 7B, FIG. 8A to FIG. 8D, and FIG. 9 to FIG. 19 depict structures at various stages of forming the resistive memory devices described herein.

As used herein, “deposition techniques” refer to the process of applying a material over another material (or the substrate). Exemplary techniques for deposition include, but are not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Additionally, “patterning techniques” include deposition of material or photoresist, patterning, exposure, development, etching, cleaning, and/or removal of the material or photoresist as required in forming a described pattern, structure, or opening. Examples of techniques for patterning include, but are not limited to, wet etch lithographic processes, dry etch lithographic processes, or direct patterning processes. Such techniques may use mask sets and mask layers.

Referring to FIG. 7A and FIG. 7B, a structure for use in the fabrication of the resistive memory devices described herein may include a dielectric layer 148 and an etch stop layer 146 formed on the dielectric layer 148. Formation of the dielectric layer 148 and the etch stop layer 146 may be performed in a BEOL processing of an integrated circuit (IC) chip. A dielectric layer 164 may be formed on the etch stop layer 146 using the deposition techniques described herein. A patterned resist layer 174 may be formed on the dielectric layer 164 using the deposition techniques and the patterning techniques described herein. In the example shown in FIG. 7B, interconnect vias 134, 136, 138 may be formed in the dielectric layer 164 and conductive lines 140, 142, 144 may be formed in the dielectric layer 148. The patterned resist layer 174 may be formed vertically above the interconnect vias 134, 136, 138.

Referring to FIG. 8A to FIG. 8D (FIG. 8A and FIG. 8B continue from the structures shown in FIG. 7A, while FIG. 8C and FIG. 8D continue from the structures shown in FIG. 7B), dielectric pillars 120, 122, 124 may be formed by patterning the dielectric layer 164 using the patterning techniques described herein. Cavities 130, 132 may be formed between the respective dielectric pillars 120, 122, 124. In the examples shown in FIG. 8A and FIG. 8C, the patterning of the dielectric layer 164 may be stopped upon reaching the underlying etch stop layer 146. The cavities 130, 132 may have bottoms that are positioned on or directly on the etch stop layer 146. Alternatively, in the examples shown in FIG. 8B and FIG. 8D, the patterning of the dielectric layer 164 may be controlled such that the dielectric layer 164 remains below the dielectric pillars 120, 122, 124. In other words, the dielectric pillars 120, 122, 124 may be integrally formed with the dielectric layer 164, and the cavities 130, 132 may have bottoms that are positioned on or directly on the dielectric layer 164. The resist layer 174 may be removed subsequently.

Referring to FIG. 9 (FIG. 9 continues from the structure shown in FIG. 8A), dielectric caps 158, 160, 162 may be formed on the respective dielectric pillars 120, 122, 124. The dielectric caps 158, 160, 162 may be formed by depositing a dielectric material on the respective upper surfaces of the dielectric pillars 120, 122, 124 using a non-conformal deposition process, such as a plasma-enhanced chemical vapor deposition (PECVD). The term “non-conformal deposition” may refer to a deposition technique that causes the deposited material to have a non-uniform thickness.

Referring to FIG. 10 (FIG. 10 continues from the structure shown in FIG. 9), an electrode layer 105 may be formed on the dielectric caps 158, 160, 162, the respective side surfaces of the dielectric pillars 120, 122, 124, and the etch stop layer 146. The formation of the electrode layer 105 may utilize a non-conformal deposition technique such as a physical vapor deposition. The term “non-conformal deposition” refers to a deposition technique in which the deposited material layer has a non-uniform thickness.

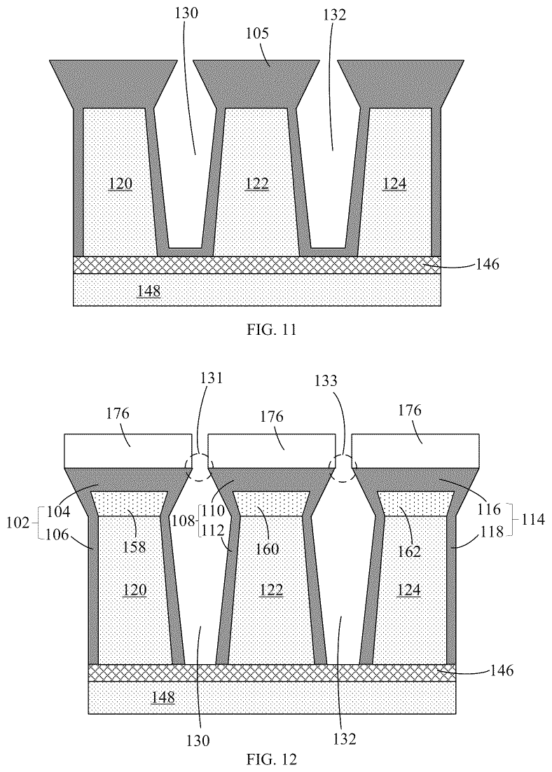

Referring to FIG. 11 (FIG. 11 continues from the structure shown in FIG. 8A), an alternative step of forming the electrode layer 105 is presented. An electrode layer 105 may be formed directly on the upper surface of the dielectric pillars 120, 122, 124. The electrode layer 105 may also be formed on the side surfaces of the dielectric pillars 120, 122, 124 and the etch stop layer 146. The formation of the electrode layer 105 may utilize a non-conformal deposition technique such as a physical vapor deposition.

Referring to FIG. 12 (FIG. 12 continues from the structure shown in FIG. 10), the electrode layer 105 may be etched in a vertical direction (e.g., anisotropic etching) to form bottom electrodes 102, 108, 114 and expose portions of the etch stop layer 146 directly below the bottom of the cavities 130, 132. A resist layer 176 may be formed to cover portions of the electrode layer 105 that are vertically above the dielectric pillars 120, 122, 124 to prevent the loss of material during the anisotropic etching. The resist layer 176 may be removed subsequently. Each of the bottom electrodes 102, 108, 114 may be formed to have a top segment 104, 110, 116, respectively, and a bottom segment 106, 112, 118, respectively. As described above, each of the top segments 104, 110, 116 of the respective bottom electrodes 102, 108, 114 may have an upper surface and a side surface. The side surface of the top segment 104, 110, 116 of each bottom electrode 102, 108, 114 may meet the upper surface of the top segment 104, 110, 116 of each bottom electrode 102, 108, 114 to provide a bottom electrode top edge. The bottom electrode top edges may form overhangs extending over the respective cavities 130, 132. The overhangs formed by the bottom electrode top edges may define openings 131, 133 over the respective cavities 130, 132.

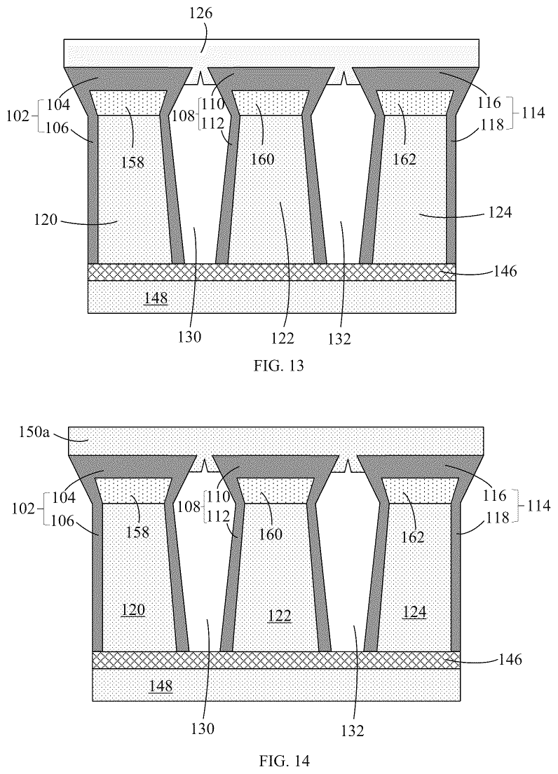

Referring to FIG. 13 (FIG. 13 continues from the structure shown in FIG. 12), a switching layer 126 may be formed on the respective top segments 104, 110, 116 of the bottom electrodes 102, 108, 114 and extend laterally over the dielectric pillars 120, 122, 124. The switching layer 126 may also cover the openings 131, 133 over the respective cavities 130, 132 such that the switching layer 126 may seal (i.e., pinch off) the openings 131, 133 over the respective cavities 130, 132. The switching layer 126 may be in direct contact with the respective bottom electrode top edges after sealing the openings 131, 133. Formation of the switching layer 126 may be performed using the deposition techniques described herein. The structure in FIG. 13 may be subjected to further processing. For example, a dielectric layer may be deposited on the switching layer 126, using the deposition techniques described herein, to form the structure shown in FIG. 5D. An interconnect via may be formed on the top segment 104, 110, 116 of the respective bottom electrodes 102, 108, 114 by forming openings through the deposited dielectric layer and the switching layer 126, followed by filling the openings with a conductive material.

Referring to FIG. 14 (FIG. 14 continues from the structure shown in FIG. 12), a dielectric layer 150a may be formed on the respective top segments 104, 110, 116 of the bottom electrodes 102, 108, 114 and extend laterally over the dielectric pillars 120, 122, 124. The dielectric layer 150a may also cover the openings 131, 133 over the respective cavities 130, 132 such that the dielectric layer 150a may seal (i.e., pinch off) the openings 131, 133 over the respective cavities 130, 132. Formation of the dielectric layer 150a may be performed using the deposition techniques described herein.

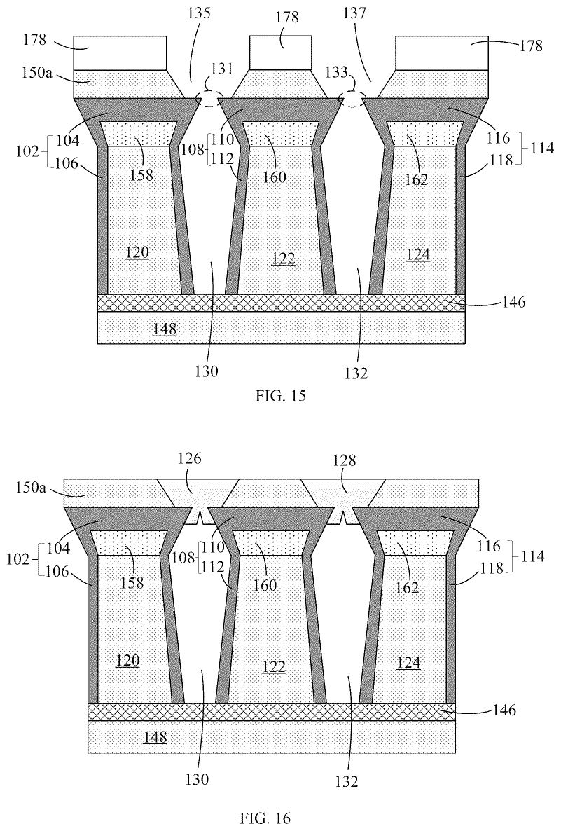

Referring to FIG. 15 (FIG. 15 continues from the structure shown in FIG. 14), the dielectric layer 150a may be etched to form openings 135, 137 using the patterning techniques described herein. A patterned resist layer 178 may be formed on the dielectric layer 150a to cover areas on the dielectric layer 150a that are to be protected from the etchant while areas on the dielectric layer 150a that are not covered by the resist layer 178 may be etched. The resist layer 178 may be removed after the etching. The formation of the openings 135, 137 in the dielectric layer 150a may reopen the openings 131, 133 over the respective cavities 130, 132.

Referring to FIG. 16 (FIG. 16 continues from the structure shown in FIG. 15), a first switching layer 126 may be formed in the opening 135 and a second switching layer 128 may be formed in the opening 137. The formation of the switching layers 126, 128 may seal the openings 131, 133 over the respective cavities 130, 132 such that the switching layers 126, 128 are in direct contact with the respective bottom electrode top edges. The switching layers 126, 128 may be formed using the deposition techniques described herein and the use of a chemical mechanical planarization (CMP) process.

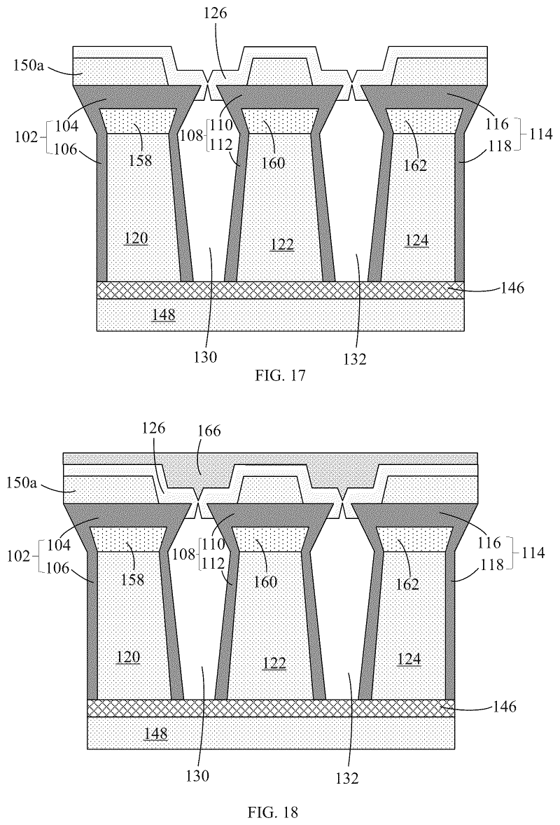

Referring to FIG. 17 (FIG. 17 continues from the structure shown in FIG. 12), a switching layer 126 may be formed in the openings 135, 137 in the dielectric layer 150a using a conformal deposition process, such as an ALD process or a highly-conformal CVD process. The openings 135, 137 in the dielectric layer 150a may be partially filled by the switching layer 126. The switching layer 126 may seal the openings 131, 133 over the respective cavities 130, 132 such that the switching layer 126 is in direct contact with the respective bottom electrode top edges. The switching layer 126 may extend laterally over the dielectric pillars 120, 122, 124.

Referring to FIG. 18 (FIG. 18 continues from the structure shown in FIG. 17), a top electrode 166 may be formed on the switching layer 126 using the deposition techniques described herein. The deposited top electrode 166 may extend laterally over the dielectric pillars 120, 122, 124. The structure in FIG. 18 may be subjected to further processing. For example, a dielectric layer may be deposited on the top electrode 166, using the deposition techniques described herein, to form the structure shown in FIG. 6D.

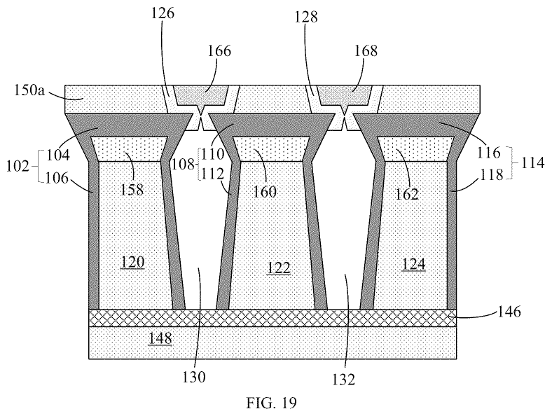

Referring to FIG. 19 (FIG. 19 continues from the structure shown in FIG. 18), a CMP process may be performed on the top electrode and the switching layer illustrated in FIG. 18 to form a first top electrode 166, a first switching layer 126, a second top electrode 168, and a second switching layer 128. The structure in FIG. 19 may be subjected to further processing. For example, an additional dielectric material may be deposited on the dielectric layer 150a to cover the top electrodes 166, 168 and the switching layers 126, 128, using the deposition techniques described herein. To form the structure shown in FIG. 2B, interconnect vias may be formed on the top segments of the bottom electrode and the top electrodes by forming openings through the dielectric layer 150a, and then filling the openings with a conductive material.

Although the structures illustrated in FIG. 9 to FIG. 19 are based on the structure shown in FIG. 8A, it should be noted that the processes described in FIG. 9 to FIG. 19 are also applicable to the structures shown in FIG. 8B, FIG. 8C, and FIG. 8D.

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description. Additionally, the various tasks and processes described herein may be incorporated into a more comprehensive procedure or process having additional functionality not described in detail herein.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

As will be readily apparent to those skilled in the art upon a complete reading of the present application, the disclosed semiconductor devices and methods of forming the same may be employed in manufacturing a variety of different integrated circuit products, including, but not limited to, memory cells, NV memory devices, FinFET transistor devices, CMOS devices, etc.

What is claimed is:

1. A resistive memory device comprising:
a first dielectric pillar having an upper surface;
a second dielectric pillar adjacent to the first dielectric pillar, the second dielectric pillar having an upper surface;
a first bottom electrode having a top segment on the upper surface of the first dielectric pillar, the top segment of the first bottom electrode includes an upper surface and a side surface, the side surface of the top segment meets the upper surface of the top segment to provide a first bottom electrode top edge;
a second bottom electrode having a top segment disposed on the upper surface of the second dielectric pillar, the top segment of the second bottom electrode includes an upper surface and a side surface, the side surface of the top segment meets the upper surface of the top segment to provide a second bottom electrode top edge;
a switching layer laterally between the first bottom electrode and the second bottom electrode, the switching layer is in direct contact with the first bottom electrode top edge and the second bottom electrode top edge; and
a cavity defined laterally between the first dielectric pillar and the second dielectric pillar, the cavity is bounded by at least the first bottom electrode, the second bottom electrode, and the switching layer, wherein the switching layer is positioned over the cavity.

2. The resistive memory device of claim 1, wherein the first bottom electrode top edge and the second bottom electrode top edge form overhangs extending over the cavity.

3. The resistive memory device of claim 1, further comprising a top electrode positioned on the switching layer.

4. The resistive memory device of claim 3, wherein the top electrode includes a bottom surface and a protrusion extending from the bottom surface of the top electrode into the switching layer.

5. The resistive memory device of claim 4, wherein the switching layer and the top electrode extend laterally over the first dielectric pillar and the second dielectric pillar.

6. The resistive memory device of claim 1, wherein the switching layer extends laterally over the first dielectric pillar and the second dielectric pillar.

7. The resistive memory device of claim 1, wherein the first dielectric pillar has side surfaces, the second dielectric pillar has side surfaces, the first bottom electrode has a bottom segment on the side surfaces of the first dielectric pillar, and the second bottom electrode has a bottom segment of the side surfaces of the second dielectric pillar.

8. The resistive memory device of claim 1, further comprising an interlayer dielectric below the first dielectric pillar and the second dielectric pillar, wherein the first dielectric pillar and the second dielectric pillar are integrally formed with the interlayer dielectric.

9. The resistive memory device of claim 1, wherein the side surface of the top segment of the first bottom electrode forms an acute angle with the upper surface of the top segment of the first bottom electrode and the side surface of the top segment of the second bottom electrode forms an acute angle with the upper surface of the top segment of the second bottom electrode.

10. A resistive memory device comprising:
a first dielectric pillar having an upper surface;
a second dielectric pillar adjacent to the first dielectric pillar, the second dielectric pillar having an upper surface;
a first dielectric cap on the upper surface of the first dielectric pillar;
a second dielectric cap on the upper surface of the second dielectric pillar;
a first bottom electrode having a top segment covering the first dielectric cap, the top segment of the first bottom electrode includes an upper surface and a side surface, the side surface of the top segment meets the upper surface of the top segment to provide a first bottom electrode top edge;
a second bottom electrode having a top segment covering the second dielectric cap, the top segment of the second bottom electrode includes an upper surface and a side surface, the side surface of the top segment meets the upper surface of the top segment to provide a second bottom electrode top edge;
a switching layer laterally between the first bottom electrode and the second bottom electrode, the switching layer is in direct contact with the first bottom electrode top edge and the second bottom electrode top edge; and
a cavity defined laterally between the first dielectric pillar and the second dielectric pillar, the cavity is bounded by at least the first bottom electrode, the second bottom electrode, and the switching layer, wherein the switching layer is positioned over the cavity.

11. The resistive memory device of claim 10, wherein the first bottom electrode top edge and the second bottom electrode top edge form overhangs extending over the cavity.

12. The resistive memory device of claim 10, wherein the first dielectric cap includes an upper surface and a side surface, the side surface of the first dielectric cap forms an acute angle with the upper surface of the first dielectric cap, and the second dielectric cap includes an upper surface and a side surface, the side surface of the second dielectric cap forms an acute angle with the upper surface of the second dielectric cap.

13. The resistive memory device of claim 12, wherein the first bottom electrode has a bottom segment on the side surface of the first dielectric cap and the second bottom electrode has a bottom segment of the side surface of the second dielectric cap.

14. The resistive memory device of claim 13, wherein the first dielectric pillar has side surfaces, the second dielectric pillar has side surfaces, the bottom segment of the first bottom electrode extends to lie on the side surfaces of the first dielectric pillar, and the bottom segment of the second bottom electrode extends to lie on the side surfaces of the second dielectric pillar.

15. The resistive memory device of claim 10, further comprising a top electrode positioned on the switching layer.

16. The resistive memory device of claim 15, wherein the top electrode includes a bottom surface and a protrusion extending from the bottom surface of the top electrode into the switching layer.

17. The resistive memory device of claim 16, wherein the switching layer and the top electrode extend laterally over the first dielectric pillar and the second dielectric pillar.

18. The resistive memory device of claim 10, wherein the switching layer extends laterally over the first dielectric pillar and the second dielectric pillar.

19. The resistive memory device of claim 10, further comprising an interlayer dielectric below the first dielectric pillar and the second dielectric pillar, wherein the first dielectric pillar and the second dielectric pillar are integrally formed with the interlayer dielectric.

20. The resistive memory device of claim 10, wherein the side surface of the top segment of the first bottom electrode forms an acute angle with the upper surface of the top segment of the first bottom electrode, and the side surface of the top segment of the second bottom electrode forms an acute angle with the upper surface of the top segment of the second bottom electrode.
